(19) United States
(12) Patent Application Publication
(10) Pub. No.: US 2009/0112497 A1
(43) Pub. Date: Apr. 30, 2009

(54) SYSTEM AND METHOD FOR AUTOMATIC VOLTAGE MEASUREMENTS OF AN ELECTRONIC SIGNAL

(75) Inventors: SHEN-CHUN LI, Tu-Cheng (TW); SHOU-KUO HSU, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/168,869

(22) Filed: Jul. 7, 2008

(30) Foreign Application Priority Data
Oct. 31, 2007 (CN) 200710202324.3

(51) Int. Cl. G01R 19/00

(52) U.S. Cl. 702/64

(57) ABSTRACT

A computer-based method for measuring a ringup, a ringdown and a ringback of an electronic signal is provided. The method includes fitting a ringdown fitting curve to approximate a first ringdown data, and fitting a ringup fitting curve to approximate a first ringup data. The method further includes calculating an approximate ringdown value according to the ringdown fitting curve, and calculating an approximate ringup value according to the ringup fitting curve. The approximate ringup and ringdown values are then used to obtain an accurate ringup value and an accurate ringup value respectively. An accurate ringback value is calculated by subtracting the accurate ringup value from the accurate ringdown value.

### 1. FIELD OF THE INVENTION

Embodiments of the present disclosure relate to systems and methods for signal measurements, and more particularly to systems and methods for measuring voltages of an electronic signal.

### 2. DESCRIPTION OF RELATED ART

Characterizing an electronic signal may include measuring various time and voltage measurements of the electronic signal. Time measurements may include measurements, such as a period, a rise time, and a fall time, for example. Voltage measurements may include measurements, such as an overshoot, an undershoot, an amplitude, and a ringback, for example.

FIG. 1 illustrates one example of several voltage measurements of an electronic signal, wherein a vertical axis of FIG. 1 represents voltage, a horizontal axis of FIG. 1 represents time, and “a” denotes an overshoot, “b” denotes an undershoot, “c” denotes a DC voltage high, “d” denotes a DC voltage low, “e” denotes a ringdown, “f” denotes a ringup, “g” denotes an amplitude, and “h” denotes a ringback.

Measuring instruments, such as oscilloscope can make some automatic voltage measurements of an electronic signal, such as an overshoot, an undershoot, and an amplitude. However, there is no measuring instrument that can automatically measure a ringdown, a ringup, and a ringback of an electronic signal. Thus, a user often has to manually identify the locations of a ringdown and a ringup in the waveforms of electronic signals, and then measures their values respectively.

What is needed, therefore, is a system and method for measuring various voltage measurements of an electronic signal, wherein increased accuracy and efficiency of the measurements can be achieved.

### SUMMARY

In one aspect, a system for measuring a ringup, a ringdown and a ringback of an electronic signal is provided. The system comprises a data selecting, a curve fitting module, a first calculating module, a second calculating module, and at least one processor. The data selecting module is configured for reading test data from a test instrument, and is further configured for selecting a first ringdown data and a first ringup data from the test data. The curve fitting module is configured for fitting a ringdown fitting curve to approximate the first ringdown data, and is further configured for fitting a ringup fitting curve to approximate the first ringup data. The first calculating module is configured for calculating an approximate ringdown value according to the ringdown fitting curve, and is further configured for calculating an approximate ringup value according to the ringup fitting curve. The second calculating module is configured for calculating an accurate ringdown value based on the approximate ringdown value, is configured for calculating an accurate ringup value based on the approximate ringup value, and is further configured for calculating an accurate ringback value. The processor executes that data selecting module, the curve fitting module, the first calculating module, and the second calculating module.

In another aspect, a computer-based method for measuring a ringup, a ringdown and a ringback of an electronic signal is provided. The method comprises: reading test data from a test instrument, and selecting a first ringdown data and a first ringup data from the test data; fitting a ringdown fitting curve f₁(x) to approximate the first ringdown data, and fitting a ringup fitting curve f₂(x) to approximate the first ringup data; calculating an approximate ringdown value according to the ringdown fitting curve f₁(x), and calculating an approximate ringup value according to the ringup fitting curve f₂(x); calculating an accurate ringdown value based on the approximate ringdown value, and calculating an accurate ringup value based on the approximate ringup value; and calculating an accurate ringback value by subtracting the accurate ringup value from the accurate ringdown value.

In still another aspect, a computer-based method for measuring a ringup, a ringdown and a ringback of an electronic signal is provided. The method comprises: reading test data from a test instrument, and selecting a first ringdown data and a first ringup data from the test data, wherein the test data is depicted as {(xᵢ,yᵢ)}, the first ringdown data is depicted as {(xⱼ,yⱼ)}, and the first ringup data is depicted as {(xₖ,yₖ)}; fitting a ringdown fitting curve f₁(x) with a domain {xⱼ} to approximate the first ringdown data, and fitting a ringup fitting curve f₂(x) with a domain {xₖ} to approximate the first ringup data; calculating all local minima of the ringdown fitting curve f₁(x) and calculating all local maxima of the ringup fitting curve f₂(x); selecting a minimum of the local minima of the ringdown fitting curve f₁(x) as an approximate ringdown value, and selecting a maximum of the local maxima of the ringup fitting curve f₂(x) as an approximate ringup value, wherein the approximate ringdown value is depicted as f₁(x₁₀), and the approximate ringup value is depicted as f₂(x₂₀); selecting a second ringdown data from the first ringdown data according to the approximate ringdown value, and selecting a second ringup data from the first ringup data according to the approximate ringup value; selecting a minimum of the second ringdown data as an accurate ringdown value, and selecting a maximum of the second ringup data as an accurate ringup value; and calculating an accurate ringback value by subtracting the accurate ringup value from the accurate ringdown value.

In yet another aspect, a computer-readable medium having stored thereon instructions for measuring a ringup, a ringdown and a ringback of an electronic signal is provided. When executed by a computer, the instructions cause the computer to: read test data from a test instrument, and select a first ringdown data and a first ringup data from the test data; fit a ringdown fitting curve f₁(x) to approximate the first ringdown data, and fit a ringup fitting curve f₂(x) to approximate the first ringup data; calculate an approximate ringdown value according to the ringdown fitting curve f₁(x), and calculate an approximate ringup value according to the ringup fitting curve f₂(x); calculate an accurate ringdown value based on the approximate ringdown value, and calculate an accurate ringup value based on the approximate ringup value; calculate an accurate ringback value by subtracting the accurate ringup value from the accurate ringdown value.

Other objects, advantages and novel features will become more apparent from the following detailed description of certain embodiments of the present disclosure when taken in conjunction with the accompanying drawings, in which:

### BRIEF DESCRIPTION OF THE DRAWINGS

FIG. 1 illustrates one embodiment of several voltage measurements of an electronic signal;

FIG. 2 is a block diagram of one embodiment of a system comprising function modules for measuring voltage measurements of an electronic signal;

FIG. 3 is one embodiment of a voltage waveform of an electronic signal varying over time;

FIG. 4 illustrates one embodiment of local minima of a ringdown fitting curve f₁(x);

FIG. 5 illustrates one embodiment of local maxima of a ringup fitting curve f₂ (x);

FIG. 6 illustrates one embodiment of a method for calculating an accurate ringdown value from the first ringdown data;

FIG. 7 illustrates one embodiment of a method for calculating an accurate ringup value from the first ringup data; and

FIG. 8 is a flowchart of one embodiment of a method for measuring various voltage characteristics, such as a ringdown, a ringup, and a ringback from an electronic signal.

### DETAILED DESCRIPTION OF CERTAIN INVENTIVE EMBODIMENTS

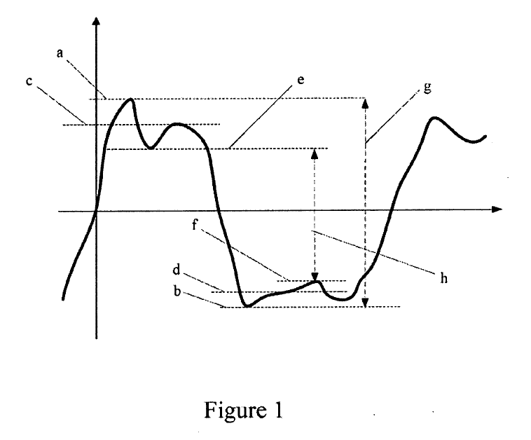

As used herein, the term, “ringdown” may be defined as a lowest edge of vibration in a stable range of a positive half-wave of an electronic signal. Likewise, the term, “ringup” may be defined as a lowest edge of vibration in a stable range of a negative half-wave of an electronic signal. Accordingly, the term, “ringback” may be defined as a difference between a ringdown and a ringup. It may be understood that the term, “data” may refer to a single data item or may refer to a plurality of data items. These terms, with reference to the FIGS. 1-8, will be described in greater detail below.

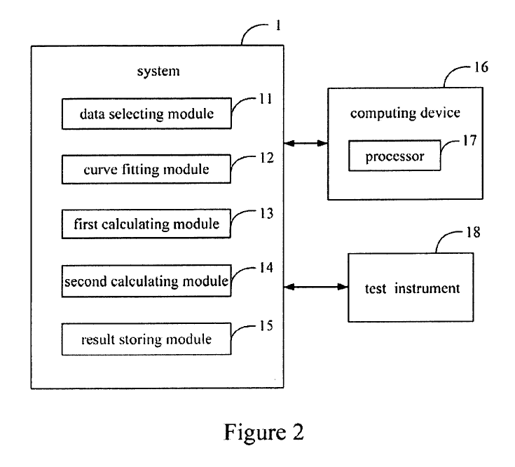

FIG. 2 is a block diagram of one embodiment of a system 1 comprising function modules for measuring voltage measurements of an electronic signal. The system 1 includes a data selecting module 11, a curve fitting module 12, a first calculating module 13, a second calculating module 14, and a result storing module 15. The system 1 may be executed by a computing device 16, such as a personal computer, for example. It may be understood that the computing device 16, may comprise one or more processors, such a processor 17 to compute the various modules 11, 12, 13, 14, 15 of the system 1.

The data selecting module 11 is configured for reading test data from a test instrument (e.g., an oscilloscope, multimeter, data acquisition unit (DAQ)) 18. The data selecting module 11 is further configured for selecting two sets of data from the test data comprising a ringdown and a ringup of an electronic signal. The test data is depicted as {(xᵢ,yᵢ)}, wherein xᵢ denotes a time, and yᵢ denotes a voltage at time xᵢ.

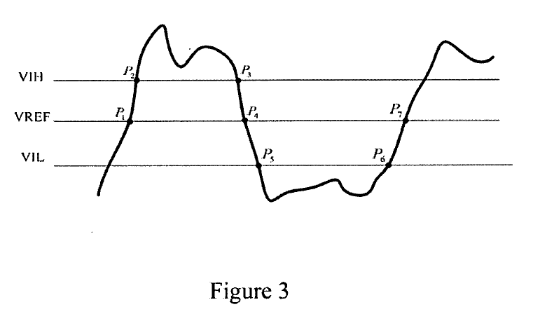

FIG. 3 is one embodiment of a voltage waveform of an electronic signal varying over time. In the embodiment of FIG. 3, an input high voltage (VIH), a reference voltage (VREF), and an input low voltage (VIL) may be defined over one period. It may be understood that the terms VIH, VREF, and VREF are well-known terms in the field of circuit design. Accordingly, seven feature points of interest (“P₁” through “P₇”) may be derived from the electronic signal. In the embodiment of FIG. 3, a ringdown is located between an interval P₂˜P₃ and a ringup is located between an interval P₅˜P₆. The data selecting module 11 selects a set of data in the interval of P₂˜P₃ (thereinafter, “the first ringdown data”), and a set of data in the interval of P₅˜P₆ (thereinafter, “the first ringup data”) from the test data. The first ringdown data is used for measuring a ringdown, and the first ringup data is used for measuring a ringup. The first ringdown data is depicted as {(xⱼ,yⱼ)}, and the first ringup data is depicted as {(xₖ,yₖ)}, such that {(xⱼ,yⱼ)}⊂{(xᵢ,yᵢ)}, and {(xₖ,yₖ)}⊂{(xᵢ,yᵢ)}.

The curve fitting module 12 is configured for fitting a fitting curve, depicted as f₁(x), to approximate the first ringdown data (thereinafter, “the ringdown fitting curve”). The curve fitting module 12 is further configured for fitting another fitting curve, depicted as f₂(x), to approximate the first ringup data (thereinafter, “the ringup fitting curve”). The domain of f₁(x) is {xⱼ}, and the domain of f₂(x) is {xₖ}. In one embodiment, one example of a general formula for fitting curves may be as follows:

$$y \approx f ( x ) ≡ {\sum }_{i = 0}^{m} {a}_{i} {φ}_{i} ( x ) = {a}_{0} {φ}_{0} ( x ) + {a}_{1} {φ}_{1} ( x ) + … + {a}_{m} {φ}_{m} ( x ) ,$$

wherein f(x) is a fitting curve to a given set of data (e.g., {(xⱼ,yⱼ)}), φᵢ(x)(i=0,1,2, . . . ,m) is a group of linear independent functions, and aᵢ(i=0,1,2, . . . ,m) is a group of undetermined coefficients. Polynomials are one of the most commonly used types of fitting curves to approximate a given set of data. In one example, setting φᵢ(x)=xⁱ,i=0,1,2, . . . ,m, then

$$y \approx f ( x ) ≡ {\sum }_{i = 0}^{m} {a}_{i} {φ}_{i} ( x ) = {a}_{0} + {a}_{1} {x}^{1} + {a}_{2} {x}^{2} + … + {a}_{m} {x}^{m} .$$

Depending on the embodiment, a Legendre polynomial, a Chebyshev polynomial, or a trigonometric polynomial may also be used to approximate a given set of data. In one embodiment, to determine the undetermined coefficients of the above mentioned equation, the method of least squares may be used. In one embodiment, the method of least squares may be defined by minimizing the value of

$${\sum }_{i = 0}^{n} {[ f ( {x}_{i} ) - {y}_{i} ]}^{2} .$$

However, in another embodiment, a fitting curve for an electronic signal may also be obtained by using other methods, such as a simplex method or a quasi-Newton method, for example.

The first calculating module 13 is configured for calculating an approximate ringdown value by evaluating a local minimum of f₁(x) and an approximate ringup value by evaluating a local maximum of f₂(x).

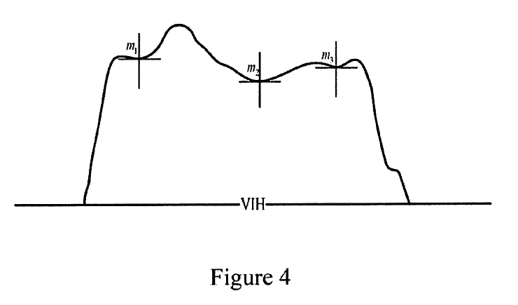

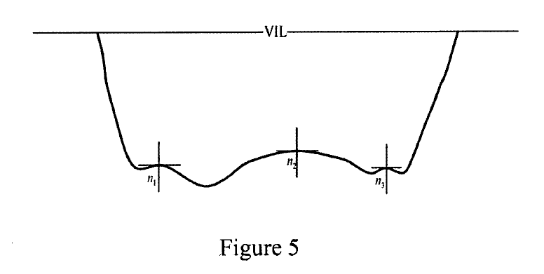

The ringdown value may be defined as a local minimum of f₁(x), and the ringup value may be defined as a local maximum of f₂(x). According to the second derivative test, the first calculating module 13 calculates a first order differential and a second order differential of f₁(x) for each xⱼ, so as to obtain a first order differential set {f₁′(xⱼ)} and a second order differential set {f₁″(xⱼ)}. Likewise, the first calculating module 13 calculates a first order differential and a second order differential of f₁(x) for each xₖ, so as to obtain a first order differential set {f₂′(xₖ)} and a second order differential set {f₂″(xₖ)}. The first calculating module 13 determines each xⱼ₀ to satisfy a requirement of f₁′(xⱼ₀)=0 and a requirement of f₁″(xⱼ₀)>0, wherein xⱼ₀ε{xⱼ}. f₁(xⱼ₀) is a local minimum of f₁(x), and all the local minima of f₁(x) may be depicted as {f₁(xⱼ₀)}. Likewise, the first calculating module 13 determines each xₖ₀ to satisfy a requirement of f₂′(xₖ₀)=0 and a requirement of f₂″(xₖ₀)<0, wherein xₖ₀ε{xₖ}. f₂(xₖ₀) is a local maximum of f₂(x), and all the local maxima of f₂(x) may be depicted as {f₂(xₖ₀)}. The first calculating module 13 selects a minimum of the local minima of f₁(x) as an approximate ringdown value, and selects a maximum of the local maxima of f₂(x) as an approximate ringup value. Referring to FIG. 4, f₁(x) has three local minima m₁,m₂,m₃, and m₂ (depicted as f₁(x₁₀)) as an approximate ringdown value . Referring to FIG. 5, f₂(x) has three local maxima n₁,n₂,n₃ , and n₂ (depicted as f₂(x₂₀) ) as an approximate ringup value. In another embodiment, the local minima and the local maxima may also be obtained according to the first derivative test.

The second calculating module 14 is configured for calculating an accurate ringdown value based on the approximate ringdown value, and further configured for calculating an accurate ringup value based on the approximate ringup value. To obtain a more accurate ringdown and a more accurate ringup, the second calculating module 14 determines the accurate ringdown value from the first ringdown data, and determines the accurate ringup value from the first ringup data.

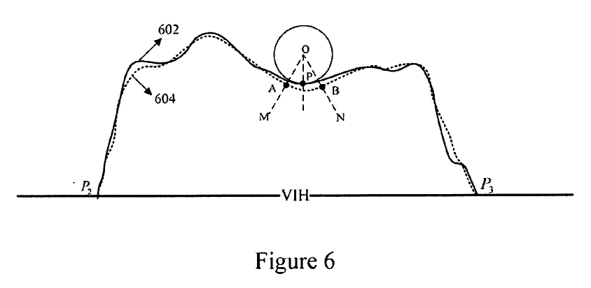

FIG. 6 illustrates one embodiment of a ringdown fitting curve f₁(x) 602, and a curve 604 of the first ringdown data (thereinafter, “the ringdown curve”). The approximate ringdown value is located at a point P(x₁₀,f₁(x₁₀)). The second calculating module 14 calculates a curvature radius at the point P, and obtains an arc, which is a part of a curvature circle at the point P with a center O. The curvature may be defined as

$$κ = {lim}_{Δs -> 0} \vert \frac{Δϕ}{Δs} \vert = \vert \frac{{f}^{″} ( x )}{{( 1 + {{f}^{′} ( x )}^{2} )}^{3 / 2}} \vert ,$$

wherein φ is a tangential angle and s is an arc length. The curvature radius may be defined as

$$r = \frac{1}{κ} = \vert \frac{{( 1 + {{f}^{′} ( x )}^{2} )}^{3 / 2}}{{f}^{″} ( x )} \vert .$$

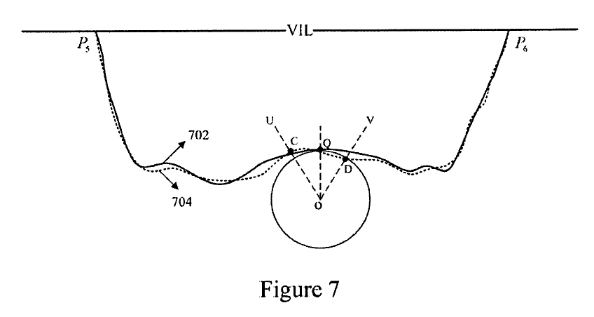

In one example, a central angle of the circle (e.g. <MON) may be 60° thus allowing <MOP=<NOP. In this particular example, OM and ON respectively intersect the ringdown curve at a point A and a point B. The second calculating module 14 selects a set of data in the interval between the point A to the point B on the ringdown curve as a second ringdown data (depicted as {y₂ⱼ}). The second calculating module 14 further compares each y₂ⱼ with every other y₂ⱼ, and selects a minimum of the second ringdown data as the accurate ringdown value. Likewise, FIG. 7 illustrates one embodiment of a ringup fitting curve f₂(x) 702, and a curve 704 of the first ringup data (thereinafter, “the ringup curve”). When the approximate ringup value is located at a point Q(x₂₀,f₂(x₂₀)), the second calculating module 14 selects a set of data in the interval between the point C to the point D on a curve of the first ringup data as a second ringup data (depicted as {y₂ₖ}), and selects a maximum of the second ringup data as the accurate ringup value. The range of the central angle may be 5°˜180° in one embodiment.

Depending on the embodiment, other sets of data may be selected as the second ringdown data from the first ringdown data. For example, an arc with a center at the point P and a radius of the curvature radius at the point P may intersect a ringdown curve at a point A′ and at a point B′. Each y′₂ⱼ in the interval between the point A′ to the point B′ is compared with every other y′₂ⱼ, and a minimum of all of the y′₂ⱼ is selected as the accurate ringdown value. Likewise, an accurate ringup value may be determined through a similar method.

The second calculating module 14 is further configured for calculating an accurate ringback value. As mentioned above, the difference between a ringdown and a ringup is a ringback. Therefore, the accurate ringback value is calculated by subtracting the accurate ringup value from the accurate ringdown value.

The result storing module 15 is configured for storing the accurate ringdown value, the accurate ringup value, and the accurate ringback value into a storage device, such as a hard disk drive.

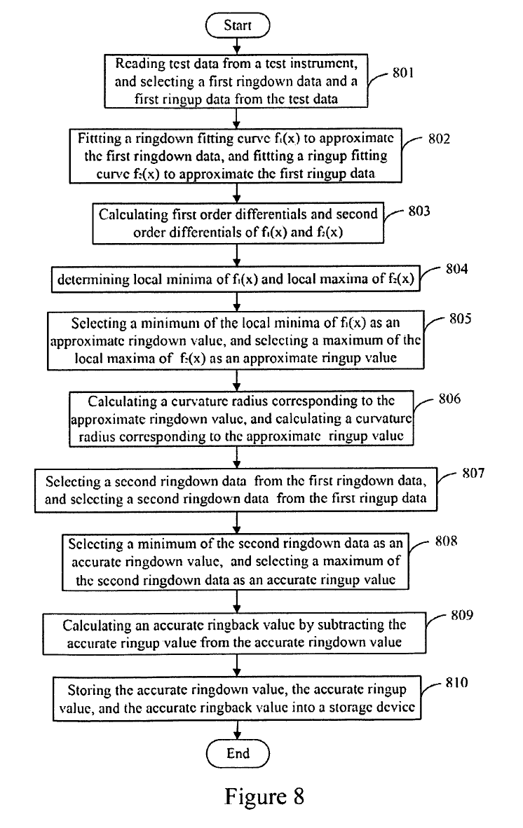

FIG. 8 is a flowchart of one embodiment of a method for measuring various voltage characteristics, such as a ringdown, a ringup, and a ringback from an electronic signal. In step 801, the data selecting module 11 reads test data from a test instrument (e.g., an oscilloscope, multimeter, data acquisition unit (DAQ)), and selects a first ringdown data and a first ringup data from the test data (Referring to FIG. 3). The first ringdown data may be used for measuring a ringdown, and the first ringup data may be used for measuring a ringup. The test data may be depicted as {(xᵢ,yᵢ)}, wherein xᵢ denotes a time, yᵢ denotes a voltage at time xᵢ. The first ringdown data may be depicted as {(xⱼ,yⱼ)}, and the first ringup data may be depicted as {(xₖ,yₖ)}, such that {(xⱼ,yⱼ)}ε{(xᵢ,yᵢ)}, and {(xₖ,yₖ)}ε{(xᵢ,yᵢ)}.

In step 802, The curve fitting module 12 fits a ringdown fitting curve f₁(x) to approximate the first ringdown data and a ringup fitting curve f₂(x) to approximate the first ringup data. The domain of f₁(x) is {xⱼ}, and the domain of f₂(x) is {xₖ}. As mentioned above, the ringdown fitting curve f₁(x) and the ringup fitting curve f₂(x), in one embodiment, are in a form as follows:

$$y \approx f ( x ) ≡ {\sum }_{i = 0}^{m} {a}_{i} {φ}_{i} ( x ) = {a}_{0} + {a}_{1} {x}^{1} + {a}_{2} {x}^{2} + … + {a}_{m} {x}^{m} ,$$

wherein aᵢ(i=0,1,2, . . . ,m) is a group of undetermined coefficients. The ringdown fitting curve f₁(x) and the ringup fitting curve f₂(x) are obtained by minimizing the value of

$${\sum }_{i = 0}^{n} {[ f ( {x}_{i} ) - {y}_{i} ]}^{2}$$

in one embodiment.

In step 803, according to a formula of a first order differential,

$${f}^{′} ( {x}_{i} ) \approx \frac{f ( {x}_{i + 1} ) - f ( {x}_{i} )}{{x}_{i + 1} - {x}_{i}} = \frac{f ( {x}_{i + 1} ) - f ( {x}_{i} )}{Δ x} ,$$

and a formula of a second order differential,

$${f}^{″} ( {x}_{i} ) \approx \frac{{f}^{′} ( {x}_{i + 1} ) - {f}^{′} ( {x}_{i} )}{{x}_{i + 1} - {x}_{i}} ,$$

the first calculating module 13 calculates a first order differential and a second order differential of f₁(x) for each xⱼ, so as to obtain a first order differential set {f₁′(xⱼ)} and a second order differential set {f₁″(xⱼ)}. Likewise, the first calculating module 13 calculates a first order differential and a second order differential of f₂(x) for each xₖ, so as to obtain a first order differential set {f₂′(xₖ)} and a second order differential set {f₂″(xₖ)}.

In step 804, the first calculating module 13 determines each xⱼ₀ to satisfy a requirement of f₁′(xⱼ₀)=0 and a requirement of f₁″(xⱼ₀)>0 according to {f₁′(xⱼ)} and {f₁″(xⱼ)}, wherein xⱼ₀ε{xⱼ}, and selects f₁(xⱼ₀) as a local minimum of f₁(x). All the local minima of f₁(x) may be depicted as {f₁(xⱼ₀)}. Likewise, the first calculating module 13 determines each xₖ₀ to satisfy a requirement of f₂′(xₖ₀)=0 and a requirement of f₂″(xₖ₀)<0 according to {f₂′(xₖ)} and {f₂(xₖ)}, wherein xₖ₀ε{xₖ}, and selects f₂(xₖ₀) as a local maximum of f₂(x). All the local maxima of f₂(x) may be depicted as {f₂(xₖ₀)}. As mentioned above, f₁(x) has three local minima m₁,m₂,m₃ in FIG. 4, and f₂(x) has three local maxima n₁,n₂,n₃ as shown in FIG. 5.

In step 805, the first calculating module 13 selects a minimum of the local minima of f₁(x) as an approximate ringdown value, and selects a maximum of the local maxima of f₂(x) as an approximate ringup value. In the embodiment of FIG. 4, m₂ (depicted as f₁(x₁₀)) is the approximate ringdown value. Similarly, in the embodiment of FIG. 5, n₂ (depicted as f₂(x₂₀)) is the approximate ringup value.

In step 806, the second calculating module 14 calculates a curvature radius at the point P(x₁₀,f₁(x₁₀)) (shown in FIG. 6) and a curvature radius at the point Q(x₂₀,f₂(x₂₀)) (shown in FIG. 7). As mentioned above, the curvature radius may be defined by

$$r = \frac{1}{κ} = \vert \frac{{( 1 + {{f}^{′} ( x )}^{2} )}^{3 / 2}}{{f}^{″} ( x )} \vert .$$

In step 807, the second calculating module 14 selects a second ringdown data (depicted as {y₂ⱼ}) from the first ringdown data according to the curvature radius at the point P(x₁₀,f₁(x₁₀)), and selects a second ringup data (depicted as {y₂ₖ}) from the first ringup data according to the curvature radius at the point Q(x₂₀,f₂(x₂₀)). As mentioned above, the second calculating module 14 selects a set of data in the interval between the point A to the point B on the ringdown curve as a second ringdown data (depicted as {y₂ⱼ}), and selects a set of data in the interval between the point C to the point D on the ringup curve as a second ringup data (depicted as {y₂ₖ}).

In step 808, the second calculating module 14 compares each y₂ⱼ with every other y₂ⱼ, and selects a minimum y₂ⱼ value as an accurate ringdown value. Likewise, the second calculating module 14 compares each y₂ₖ with every other y₂ₖ, and selects a maximum y₂ₖ value as an accurate ringup value.

In step 809, the second calculating module 14 calculates an accurate ringback value by subtracting the accurate ringup value from the accurate ringdown value.

In step 810, the result storing module 15 stores the accurate ringdown value, the accurate ringup value and the accurate ringback value into a storage device.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A system for measuring a ringup, a ringdown and a ringback of an electronic signal, the system comprising:
a data selecting module configured for reading test data from a test instrument, further configured for selecting a first ringdown data and a first ringup data from the test data;
a curve fitting module configured for fitting a ringdown fitting curve to approximate the first ringdown data, and further configured for fitting a ringup fitting curve to approximate the first ringup data;
a first calculating module configured for calculating an approximate ringdown value according to the ringdown fitting curve, and further configured for calculating an approximate ringup value according to the ringup fitting curve;
a second calculating module configured for calculating an accurate ringdown value based on the approximate ringdown value, configured for calculating an accurate ringup value based on the approximate ringup value, and further configured for calculating an accurate ringback value; and
at least one processor that executes that data selecting module, the curve fitting module, the first calculating module, and the second calculating module.

2. The system as claimed in claim 1, further comprising a result storing module configured for storing the accurate ringdown value, the accurate ringup value, and the accurate ringback value into a storage device.

3. A computer-based method for measuring a ringup, a ringdown and a ringback of an electronic signal, the method comprising:
reading test data from a test instrument, and selecting a first ringdown data and a first ringup data from the test data;
fitting a ringdown fitting curve f₁(x) to approximate the first ringdown data, and fitting a ringup fitting curve f₂(x) to approximate the first ringup data;
calculating an approximate ringdown value according to the ringdown fitting curve f₁(x), and calculating an approximate ringup value according to the ringup fitting curve f₂(x);
calculating an accurate ringdown value based on the approximate ringdown value, and calculating an accurate ringup value based on the approximate ringup value; and
calculating an accurate ringback value by subtracting the accurate ringup value from the accurate ringdown value.

4. The method as claimed in claim 3, further comprising:
storing the accurate ringdown value, the accurate ringup value and the accurate ringback value into a storage device.

5. The method as claimed in claim 3, wherein the ringdown fitting curve f₁(x) and the ringup fitting curve f₂(x) are in a form as follows:
$$f ( x ) ≡ {\sum }_{i = 0}^{m} {a}_{i} {φ}_{i} ( x ) = {a}_{0} {φ}_{0} ( x ) + {a}_{1} {φ}_{1} ( x ) + … + {a}_{m} {φ}_{m} ( x ) ,$$
wherein φᵢ(x) ( i=0,1,2, . . . ,m ) is a group of linear independent functions, and aᵢ (i=0,1,2, . . . ,m) is a group of undetermined coefficients.

6. The method as claimed in claim 5, wherein φᵢ(x)=xⁱ,i=0,1,2, . . . ,m.

7. A computer-based method for measuring a ringup, a ringdown and a ringback of an electronic signal, the method comprising steps of:
(a) reading test data from a test instrument, and selecting a first ringdown data and a first ringup data from the test data, wherein the test data is depicted as {(xᵢ, yᵢ)}, the first ringdown data is depicted as {(xⱼ,yⱼ)}, and the first ringup data is depicted as {(xₖ,yₖ)};
(b) fitting a ringdown fitting curve f₁(x) with a domain {xⱼ} to approximate the first ringdown data, and fitting a ringup fitting curve f₂(x) with a domain {xₖ} to approximate the first ringup data;
(c) calculating all local minima of the ringdown fitting curve f₁(x) and calculating all local maxima of the ringup fitting curve f₂(x);
(d) selecting a minimum of the local minima of the ringdown fitting curve f₁(x) as an approximate ringdown value, and selecting a maximum of the local maxima of the ringup fitting curve f₂(x) as an approximate ringup value, wherein the approximate ringdown value is depicted as f₁(x₁₀), and the approximate ringup value is depicted as f₂(x₂₀);
(e) selecting a second ringdown data from the first ringdown data according to the approximate ringdown value, and selecting a second ringup data from the first ringup data according to the approximate ringup value;
(f) selecting a minimum of the second ringdown data as an accurate ringdown value, and selecting a maximum of the second ringup data as an accurate ringup value; and
(g) calculating an accurate ringback value by subtracting the accurate ringup value from the accurate ringdown value.

8. The method as claimed in claim 7, further comprising:
storing the accurate ringdown value, the accurate ringup value and the accurate ringback value into a storage device.

9. The method as claimed in claim 7, wherein the ringdown fitting curve f₁(x) and the ringup fitting curve f₂(x) are in a form as follows:
$$f ( x ) ≡ {\sum }_{i = 0}^{m} {a}_{i} {φ}_{i} ( x ) = {a}_{0} {φ}_{0} ( x ) + {a}_{1} {φ}_{1} ( x ) + … + {a}_{m} {φ}_{m} ( x ) ,$$
wherein φᵢ(x) (i=0,1,2, . . . ,m ) is a group of linear independent functions, and aᵢ (i=0,1,2, . . . ,m) is a group of undetermined coefficients.

10. The method as claimed in claim 9, wherein φᵢ(x)=x,i=0,1,2, . . . ,m.

11. The method as claimed in claim 9, wherein the ringdown fitting curve f₁(x) and the ringup fitting curve f₂(x) are obtained by using a method of least squares.

12. The method as claimed in claim 7, wherein the step (c) comprises:
calculating a first order differential and a second order differential of f₁(x) for each xⱼ, and calculating a first order differential and a second order differential of f₂(x) for each xₖ; and
determining each xⱼ₀ to satisfy a requirement of f₁′(xⱼ₀)=0 and a requirement of f₁″(xⱼ₀)>0, wherein xⱼ₀ε{xⱼ}, and selecting all f₁(xⱼ₀) as local minima of f₁(x), and determining each xₖ₀ to satisfy a requirement of f₂′(xₖ₀)=0 and a requirement of f₂″(xₖ₀)<0, wherein xₖ₀ε{xₖ}, and selecting all f₂(xₖ₀) as local maxima of f₂(x).

13. The method as claimed in claim 7, wherein the step (e) comprises:
calculating a curvature radius at the point (x₁₀,f₁(x₁₀)) for f₁(x) and a curvature radius at the point (x₂₀,f₂(x₂₀)) for f₂(x); and
selecting a second ringdown data from the first ringdown data according to the curvature radius at the point (x₁₀,f₁(x₁₀)) and a central angle α of a curvature circle corresponding to the curvature radius at the point (x₁₀,f₁(x₁₀)); and selecting a second ringdown data from the first ringup data according to the curvature radius at the point (x₂₀,f₂(x₂₀)) and a central angle α of a curvature circle corresponding to the curvature radius at the point (x₂₀,f₂(x₂₀)).

14. The method as claimed in claim 13, wherein the range of the central angle α is 5 degrees to 180 degrees.

15. A computer-readable medium having stored thereon instructions for measuring a ringup, a ringdown and a ringback of an electronic signal, when executed by a computer, causing the computer to:
read test data from a test instrument, and select a first ringdown data and a first ringup data from the test data;
fit a ringdown fitting curve f₁(x) to approximate the first ringdown data, and fit a ringup fitting curve f₂(x) to approximate the first ringup data;
calculate an approximate ringdown value according to the ringdown fitting curve f₁(x), and calculate an approximate ringup value according to the ringup fitting curve f₂(x);
calculate an accurate ringdown value based on the approximate ringdown value, and calculate an accurate ringup value based on the approximate ringup value; and
calculate an accurate ringback value by subtracting the accurate ringup value from the accurate ringdown value.

16. The computer-readable medium as claimed in claim 15, having stored thereon instructions, when executed by a computer, further causing the computer to: store the accurate ringdown value, the accurate ringup value, and the accurate ringback value into a storage device.
